(19) United States
(12) Patent Application Publication
(10) Pub. No.: US 2018/0113154 A1
(43) Pub. Date: Apr. 26, 2018

(54) Electrical Measurement Assembly Suitable for Portable Work Platforms

(71) Applicant: Access Innovators, LLC, Norcross, GA (US)

(72) Inventor: Robert J. Lago, Dahlonega, GA (US)

(21) Appl. No.: 15/299,732

(22) Filed: Oct. 21, 2016

(51) Int. Cl. G01R 1/36

(52) U.S. Cl. CPC G01R 1/36

(57) ABSTRACT

A portable measurement assembly suitable for a work platform is disclosed. The assembly includes a housing that supports and protects a measurement device. The housing forms a first passage that receives a line-in electrical supply and a second passage that provides a line-out to a load. The measurement device is coupled to the line-in electrical supply. The portable measurement assembly is safe, convenient and enables an operator to determine an electrical condition at a work platform when the supply circuit is under load.

### TECHNICAL FIELD

This invention relates, in general, to suspended work platform hoist systems. More specifically, a condition of an electrical power source available on deployed work platforms.

### BACKGROUND

Portable work platforms used for interior or exterior maintenance of a specific structure or a group of similar structures are known. These platforms provide a movable horizontal work surface to support maintenance workers and their tools in the course of performing such tasks as window cleaning, caulking, metal polishing, window re-glazing, sealing and any other general maintenance task that must be performed from heights that range from a few feet above the ground or an interior ground floor to the top floor of a building, which in some circumstances can be several hundred feet above the ground. These portable work platforms are supported by structural cables and respective hoist mechanisms that enable the work platform to be controllably lowered or raised along the side of a building or other vertical structure. Such hoist mechanisms are generally simple machines including an electric induction motor, a gearbox, and a traction mechanism that grips the wire or cable. Generally, a 220 VAC power source is provided to the platform. However, other input line voltages are possible. An independent splitter connects the power source to respective inputs of electric motors in the hoist mechanisms for raising or lowering the platform on the structural cable. Generally, the electric motors are placed at opposing ends of the work platform.

The traditional electric traction hoist has been used for swing stage applications, also known as suspended scaffolding, for nearly 70 years. In the field, voltage sag has been a chronic issue at job sites for decades. With the demand for power increasing in the workplace and the home, aging power grids in many cities have struggled to provide nominal voltage levels during peak power usage hours. Voltage levels at a suspended platform will further decrease as the distance from the power source increases and as workmen on the platform energize tools and the hoist mechanisms to adjust the height of the platform. In addition, as building HVAC systems increase a local electrical load in response to the heat of the afternoon, job site voltages at the platforms can fall to a level that renders the hoists inoperable. Thus, stranding workers on swing stage equipment until an appropriately sized voltage buck/boost transformer is connected at the power source or the source voltage at the platform otherwise returns to an adequate voltage level. When this is the case, a field engineer or support technician has insufficient information as to the voltage level at the platform when under load.

Both analog and digital handheld-multimeters are well known. These electrical measuring devices are typically provided with electrically conductive leads that respectively terminate in corresponding sockets arranged on the multimeter. The leads can be used to contact the individual conductors of a disconnected connector coupled at the end of an electrical input or supply line. Thus, electrical measurements performed at an input or supply connector with a conventional multimeter are measuring an open circuit condition. Furthermore, any modification to the electrical supply circuit elements to permit handheld probe access to supply conductors on a work platform would introduce a significant safety hazard.

To date, there is no known conveniently sized measuring device available to the work platform that is capable of measuring input voltage at the platform while the hoists and possibly other electrical equipment are operating under load.

### SUMMARY

The present electrical measurement assembly provides a safe, practical, and economical solution that is suitable for use on or in connection with an electrical feed suitable for applying power to work platforms. Furthermore, the present electrical measurement assembly is compact, easy to use, store and transport.

In a first example embodiment, a portable measurement assembly suitable for work platforms includes a housing that forms a first passage arranged to receive a line-in electrical supply and a second passage arranged to provide a line-out to a load. A measurement device is electrically coupled to the line-in electrical supply.

In an alternative embodiment, a similar housing is further arranged with a hinged cover that protects the measurement device.

In another example embodiment, a similar housing is further arranged such that the third passage is aligned with an opening in a protective cover, thereby protecting a display portion of the measurement device.

### BRIEF DESCRIPTION OF THE DRAWINGS

The portable measurement assembly suitable for work platforms can be better understood with reference to the following drawings. The components in the drawings are not necessarily to scale, emphasis instead being placed upon clearly illustrating the principles of the assembly.

FIG. 1 schematically illustrates an environment where the portable electrical measurement assembly may be deployed.

FIG. 2 schematically illustrates an example embodiment of the portable electrical measurement assembly in a top plan view.

FIG. 3 schematically illustrates the portable electrical measurement assembly of FIG. 2 in a front plan view.

FIG. 4 is a circuit diagram illustrating an embodiment of the portable electrical measurement assembly of FIG. 2.

FIGS. 5A, 5B and 5C schematically illustrate an alternative embodiment of the portable electrical measurement assembly of FIG. 2 arranged with a protective cover.

FIGS. 6A and 6B schematically illustrate an alternative embodiment of the portable electrical measurement assembly in top plan and front plan views, respectively.

### DETAILED DESCRIPTION OF THE ILLUSTRATED EMBODIMENTS

To date, there has been no conveniently sized measuring device available to the work platform industry that is capable of measuring line-in voltage at the platform while the hoists and other electrical equipment are operating under load. The present electrical measurement assembly provides a safe, practical, and economical solution that is suitable for use on or in connection with work platforms. Furthermore, the present electrical measurement assembly is compact, easy to use, store and transport.

In use, the present electrical measurement assembly is inserted in line with an available source of electrical power. The assembly can be applied at either end of a supply cable. The assembly provides one or more electrical measures while energizing one or more hoist motors and other electrical equipment on a work platform. When coupled in-line and closer to a building source, the measurement assembly provides information that can confirm nominal operating conditions at that location. When coupled in-line on a work platform, the measurement assembly provides information that can confirm nominal operating conditions or provide an indication that can be communicated to a field engineer or technician as to an appropriate buck/boost transformer that may be required to provide sufficient voltage to a deployed work platform.

A number of features can be integrated into the novel and inventive electrical measurement assembly suitable for portable work platforms. As will be apparent to those skilled in the art, the separate features can be applied in any desired combination that provides convenient and operator safe access to line-in voltage information under load conditions on portable work platforms. For example, the entire assembly can be appropriately scaled in size to be stored and transported in a tool box. The assembly can be arranged with desired lengths of insulated cable each of which may be terminated in an electrically insulated and weather proof connector.

Alternatively, when a more permanent installation is desired, a platform load side cable may be terminated in an enclosure on the platform rather than a connector. An example enclosure may include a power distribution assembly that receives and distributes a first voltage to hoist mechanisms and that provides a second voltage different from the first voltage for operating one or more tools from the work platform.

Whether the electrical measurement assembly is arranged in a temporary and portable configuration (with two connectors) or a permanent configuration with one or no connectors, the cable conductors and the connectors should be sized appropriately. For example, a 10 gauge conductor is appropriate to safely support a current up to 20 amperes. When such loads are expected, corresponding connectors rated to support 250 volts with a current of 20 amperes should be used. On some work platforms and under some load conditions it may be desirable to use 8 gauge conductors and connectors rated to support 250 volts and a current up to 30 amperes. However sized and selected, such connectors are electrically insulated and weather proof may be arranged with electrically conductive sockets (commonly referred to as a female connector) or tabs (commonly referred to as a male connector) as may be desired. Furthermore, a first or line-in cable length may be different from a second or line-load cable length. Accordingly, the assembly can be arranged in unique configurations to match a layout of specific work platforms if so desired.

In preferred embodiments, the electrical measurement assembly provides an observable display of the AC line-in voltage while providing the line-in voltage to one or more hoist motors, hoist controls, and other electrically powered equipment on the work platform. At present, a measurement element with a digital display is preferred. A first terminal of the measurement element is coupled to an in-line or supply side conductor. A second terminal of the measurement element is coupled to the neutral or return conductor.

In the preferred embodiment, this first terminal is protected by a series-coupled current limiting device such as a time-delay fuse. The current limiting device can be mounted in a fourth opening along a surface of the housing. When the current limiting device is a time-delay fuse, the fuse can be inserted in a cartridge style sub-assembly mounted along a surface of the housing or in a cover of the housing. Such a cartridge-style sub-assembly is generally arranged with an external removable cap to provide replacement access to the time-delay fuse. Alternatively, the current limiting device can be arranged on an insulated mount within the housing.

Whether an analog or a digital display element is deployed, the display portion of the electrical measurement element is mounted in the housing or in a cover of the housing such that the display is observable to operators on the platform or in relative proximity of the electrical measurement assembly when the assembly is coupled in series with a line-in cable from an electrical source.

When an analog or deflection type measurement element is deployed, a graded scale or a color coded scale may be presented along a face of the display as an indicator of a nominal in-line voltage range. On the low-voltage side of the nominal range a set of labels or different colors may be applied over corresponding ranges of the analog scale as an indicator to a field engineer or a technician as to an appropriate buck/boost transformer to use at the building or other power source.

In an example embodiment, the housing may be arranged with a hinged cover that protects the measurement element. Such a hinged cover may further protect and provide access to a removable cap on a cartridge-style fuse holder. The hinged cover may be opaque and made from the same material as the housing. Alternatively, the hinged cover may be translucent and made from plastic or plexiglass. In still other alternatives the hinged cover may be arranged with a suitably sized opening in registration with a display of the measurement device. The opening may remain open or a translucent insert may be fixed in the opening to permit observation of the display of the measurement device while the hinged cover or even a permanent cover is present protecting the measuring device. Such a translucent insert can be plastic, plexiglass, or tempered glass. Alternatively, a wire or plastic screen can be applied over the opening in the cover.

In an example embodiment, the housing may be arranged with at least one mounting tab extending from a surface of the housing. Such a mounting tab or tabs may form a hole or slot that can receive an appendage that is fixed to the work platform for safely securing the electrical measurement assembly when it is on a work platform.

In the preferred embodiment, the housing is formed from four walls that extend from a base. Adjacent walls are substantially orthogonal with respect to each other and orthogonal with respect the base. Insulated cables extend from respective openings in the housing. A respective clamp may surround a respective insulated cable and provide strain relief and a weather resistant seal about each opening. In the illustrated embodiment, the insulated cables extend from respective openings in opposed walls of the housing. However, the electrical measurement assembly is not limited to this arrangement. For example, a suitable housing may be round or multifaceted with greater than four walls extending from a base and enclosed with a removable cover. By way of further example, the insulated cables may extend from openings in the same wall, adjacent walls or even the base and a wall as may be desired.

In the preferred embodiment, respective passages for a cartridge-style fuse holder and a digital voltmeter are provided in a removable cover. A respective gasket or seal may surround the respective passages or openings in the removable cover. One or both of the mating or opposed surfaces of the housing and the removable cover may be arranged with a gasket or a corresponding channel to provide a weather resistant barrier to protect the interior of the housing from moisture or contaminants.

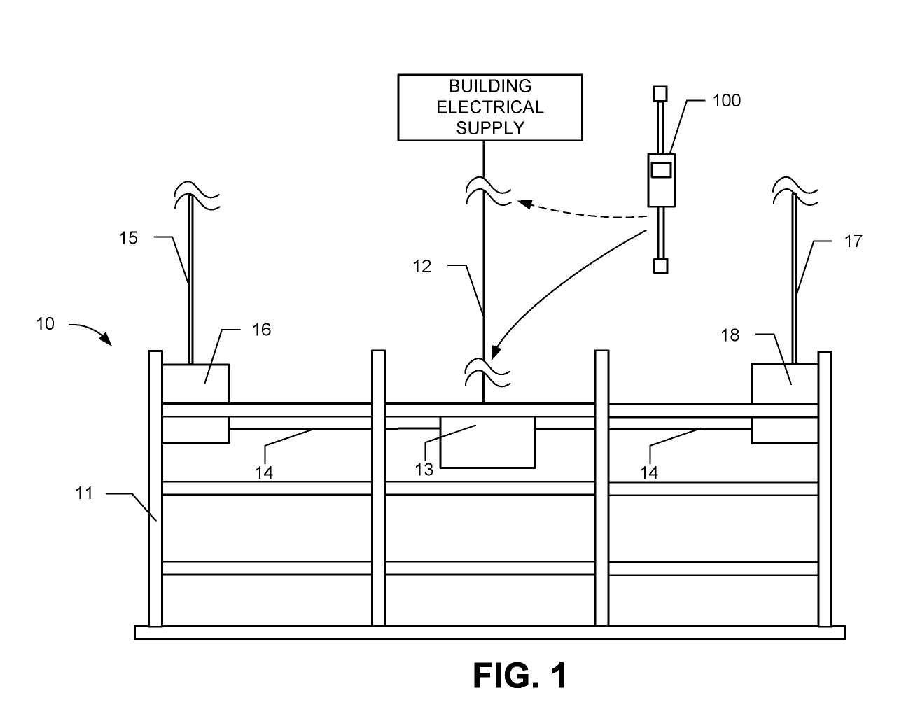

FIG. 1 illustrates an example environment where a portable electrical measurement assembly 100 may be deployed. The example environment includes a work platform 10 that is controllably suspended from a pair of suspension cables 15, 17. The suspension cables 15, 17 are typically connected to a gantry or other support structure temporarily fixed on the roof of a building. A building electrical supply is provided to the work platform 10 along a line-in electric supply 12 typically provided in the form a long flexible service cord or cable terminated with a standard electrical connector (not shown). The work platform 10 includes a frame 11 that surrounds and supports a floor upon which one or more maintenance operators may stand. The frame 11 further supports hoist mechanisms 16, 18 which include respective drive elements and motors for vertically adjusting the position of the work platform 10 along the side of the building. A distribution assembly 13 arranged along the frame 11 receives the line-in electrical supply 12 and provides a respective line-out 14 to the hoist mechanisms 16, 18. In addition, the distribution assembly 13 may include a yoke, a step-down transformer, and various devices for workers to safely energize one or more electrically powered tools from the work platform 10.

In operation, a nominal 220 VAC typically provided at a building electrical supply may sag or drop during peak power usage hours. As the work platform 10 is adjusted vertically along the side of the building further from the building electrical supply, the source voltage available at the platform 10 will also encounter an additional voltage drop due to the electrical resistance of the conductors in the line-in electric supply. This voltage drop further increases when the motors and controllers associated with the hoist mechanisms 16, 18 are enabled. This electrical load may be further increased when an operator is simultaneously energizing one or more electric motors in respective tools on the work platform 10.

As further illustrated in FIG. 1, a portable electrical measurement assembly 100 may be deployed in line at either end of the line-in electrical supply 12 to provide a real-time indication of an electrical condition. For example, when inserted in line near the building source, the portable electrical measurement assembly 100 provides a measure of the line-in condition (e.g., AC voltage) at the power source. Otherwise, when inserted closer to the work platform 10, the portable electrical measurement assembly 100 provides a measure of the line-in condition at the work platform 10. At either location, the measure of the line-condition can be presented under both load and no load conditions on the work platform 10. When the portable electrical measurement assembly 100 is connected to the line-in electrical supply 12 and the distribution assembly 13, the measure of the line-in condition is observable by an operator present on the work platform 10. Consequently, the line-in condition can be communicated to a field technician or a building maintenance worker. As will be described, the portable electrical measurement assembly 100 may be arranged to provide an indication to an operator on a suspended work platform 10 of an appropriate buck boost transformer that if connected in series at the building supply would enable an otherwise disabled work platform to be operated again.

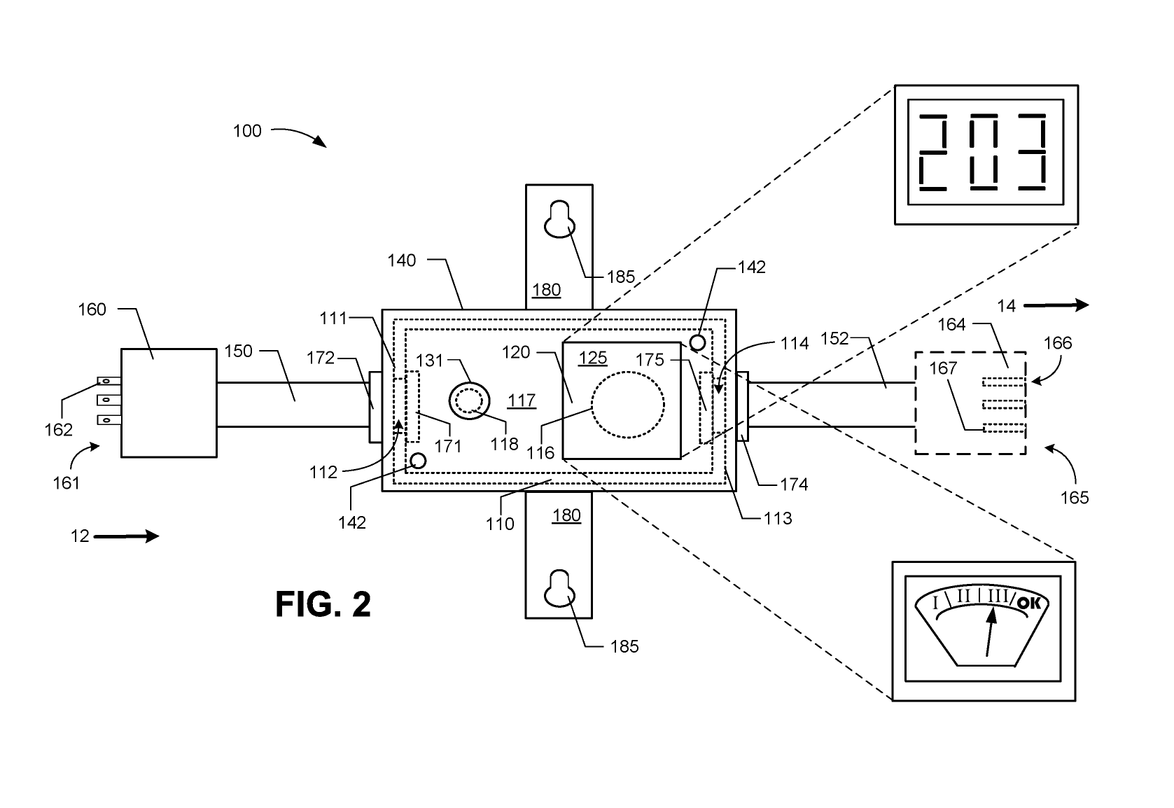

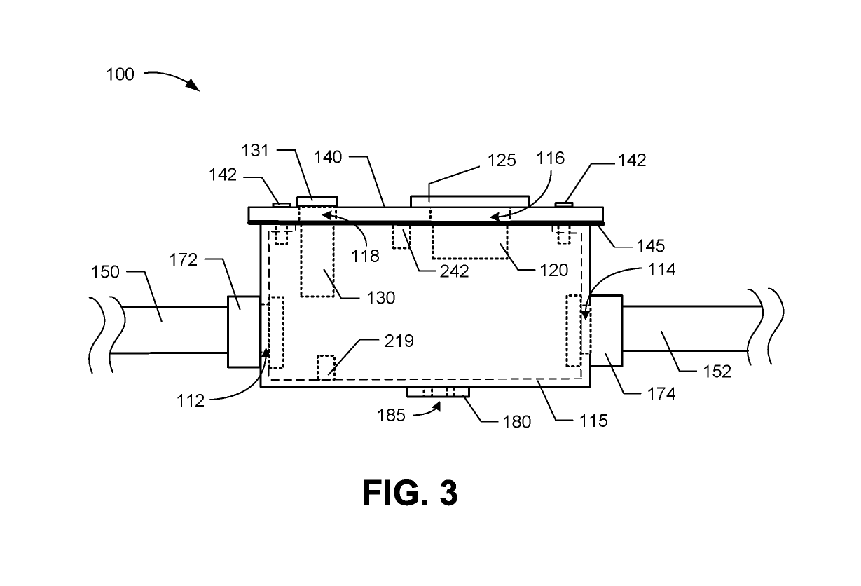

FIG. 2 and FIG. 3 schematically illustrate an example embodiment of the portable electrical measurement assembly 100. In FIG. 2, the portable electrical measurement assembly 100 is shown in a top plan view. In FIG. 3, the portable electrical measurement assembly 100 is shown in a front plan view. A housing 110 includes a base 115 and at least one wall supported by and extending from the base 115. One or more tabs 180 extend from the base 115 beyond a surface of the housing 110. The one or more tabs 180 form respective openings 185 that can pass over a hook, mount or head of a fastener arranged along a member of the frame 11 of the work platform 10. When a fastener or fasteners (not shown) are provided on the work platform 10 having a separation distance that corresponds to the distance between the openings 185 in the tabs 180, the portable electrical measurement assembly 100 may be slidingly engaged to the work platform 10 by displacement of the housing 110 in a direction opposite that of the narrower width provided by the openings 185.

Although the illustrated embodiment includes two tabs 180, the housing 110 may be supported on the work platform by a single tab 180 or more than two tabs 180. Accordingly, the housing 110 can be modified to include a single tab 180 or more than two tabs 180 as may be desired. While, the illustrated embodiment shows tabs 180 perpendicular to opposed side walls of the housing 110, one or more tabs may be arranged in other orientations with respect to one or more external facing surfaces of the housing 110. While the illustrated embodiment shows each tab 180 arranged to form a single opening 185, one or more additional openings may be added as may be desired to provide multiple options for supporting the portable electrical measurement assembly 100.

In the illustrated arrangement, the housing 110 is arranged with four walls with two opposed walls forming passages into and out from a volume defined by the base 115 and the walls extending from the base 115. Wall 111 forms an opening or passage 112 for an insulated cable 150 to pass into a volume within the housing 110. A threaded cable clamp 172 traverses the wall 111 through the opening 112 and is secured to the opposed surfaces of the wall 111 by a locknut 171 rotationally fastened against the inward facing wall. When so secured, the threaded cable clamp 172 provides a weatherproof seal about the circumference of the insulated cable 150 and the external facing surface of the wall 111. Similarly, wall 113 forms an opening or passage 114 for an insulated cable 152 to pass into the housing 110. The opening 114 supports a threaded cable clamp 174 which is secured to the opposed surfaces of the wall 113 by a locknut 175 rotationally fastened against the inward facing surface of the wall 114. When so secured, the threaded cable clamp 174 provides a weatherproof seal about the circumference of the insulated cable 152 and the external facing surface of the wall 114.

An example housing with a removable cover, sealing gasket, formed flanges, base and cover bonding structures and mounting tabs is commercially available from Hoffman Enclosures, Inc. DBA Pentair Technical Products of Anoka, Minn., U.S.A. An example threaded cable clamp is commercially available from Lapp Group USA of Florham Park, N.J., U.S.A.

A distal end of the service cord or insulated cable 150 is terminated in a plug style connector 160 which as indicated by the arrow labelled 12 can be coupled to a building or other line-in electrical supply. Specifically, the separate conductors in the insulated cable 150 are coupled in a one-to-one relationship with the conductive blades or tab(s) 162 that extend beyond the face 161 of the connector. Similarly, a distal end of the service cord or insulated cable 152 is terminated in a female style connector 164 having openings 166 in a face 165 that expose respective sockets 167 that are coupled in a one-to-one relationship with the conductors in the insulated cable 152. The tab(s) 162 in the plug-style connector 160 are labelled and keyed to ensure that a ground tab, line-in tab and a return tab are only coupled to a correspondingly arranged socket opening in a mating female style connector 164. As indicated by the arrow labelled 14 the connector 164 can be coupled to a plug style connector (not shown) coupled to a load on the work platform 10. In a preferred embodiment, after insertion of the plug-style connector 160 into a corresponding female style connector, rotation of the respective connector housings in opposed directions will controllably engage the connectors 160, 164 in a locked state.

As further illustrated in FIG. 2 and FIG. 3, a removable cover 140 is arranged with opening or passage 116 and opening or passage 118. The opening 116 is arranged to receive a body of a measurement device 120. The opening 118 is arranged to receive a cartridge-style fuse holder 130. A display 125 of the measurement device 120 remains on the exterior surface of the removable cover 140. As indicated in FIG. 2, the display 125 may be a multiple digit display that corresponds to the AC electrical potentially present on the conductors in the housing 110. While three digits are shown in the illustrated embodiment, the display 125 may include one or more additional digits to the right of a decimal point to indicate a portion of the measured electrical potential that is smaller than 1 AC volt. A scale may be provided via a label (not shown) applied to the an exterior surface of the housing 110 or the removable cover 140 where the scale identifies an appropriate buck-boost transformer that when inserted between the building supply and the work platform will adjust the line-in voltage at the work platform 10 to a desired voltage. The scale or table on the label may be color coded or otherwise marked to correspond to an appropriately sized buck-boost transformer.

Alternatively, the display 125 may be an analog style display with a deflection needle that moves linearly from a rest position when no voltage is present on the conductors to a measured voltage corresponding to a present voltage on the conductors within the housing 110. As further indicated in FIG. 2, such an analog display may be augmented with an informational label of ranges that identify an appropriately configured buck-boost transformer when the present voltage as indicated by the deflection needle corresponds to a range of voltages.

In the illustrated embodiment, a range is labeled “OK” corresponding to a range of line-in voltages that are expected to provide nominal operating conditions for equipment on the work platform 10. An adjacent range of line-in voltages is represented on the display with the label “III”. This range of voltages may correspond to a buck-boost transformer that can be inserted between the building or other electrical supply and the work platform 10 that is capable of increasing the line-in voltage to the “OK” range from the “III” range. Similarly, additional ranges of line-in voltage levels are depicted by labels “II” and “I”, respectively.

Similarly, an access cap 131 and a small portion of the length of the fuse holder 130 remains on the exterior surface of the removable cover 140 with the remaining or larger portion is confined within the housing 110. When appropriately coupled to the line-in and return conductors of the service cord or insulated cable 150 and the corresponding line-in and return conductors of the service cord or insulated cable 152, both a current limiting device in the fuse holder 130 and the measurement device 120 are coupled in-series with a load on the work platform 10.

The removable cover 140 can be fastened to the housing 110 by fasteners 142. A gasket 145 is arranged between the removable cover 140 and respective surfaces of the walls of the housing 110 such that when the fasteners 142 are tightened in the housing 110 a seal is formed between the walls and the inward facing surface of the removable cover 140. The gasket 145 is made from a non-conductive compressible material. Accordingly, the housing 110 is arranged with a bonding element 219 and the removable cover 140 is arranged with a respective bonding element 242 that separately receive and engage a respective fastener that holds a bonding conductor coupled to the ground conductor from the insulated cable 150 and the insulated cable 152.

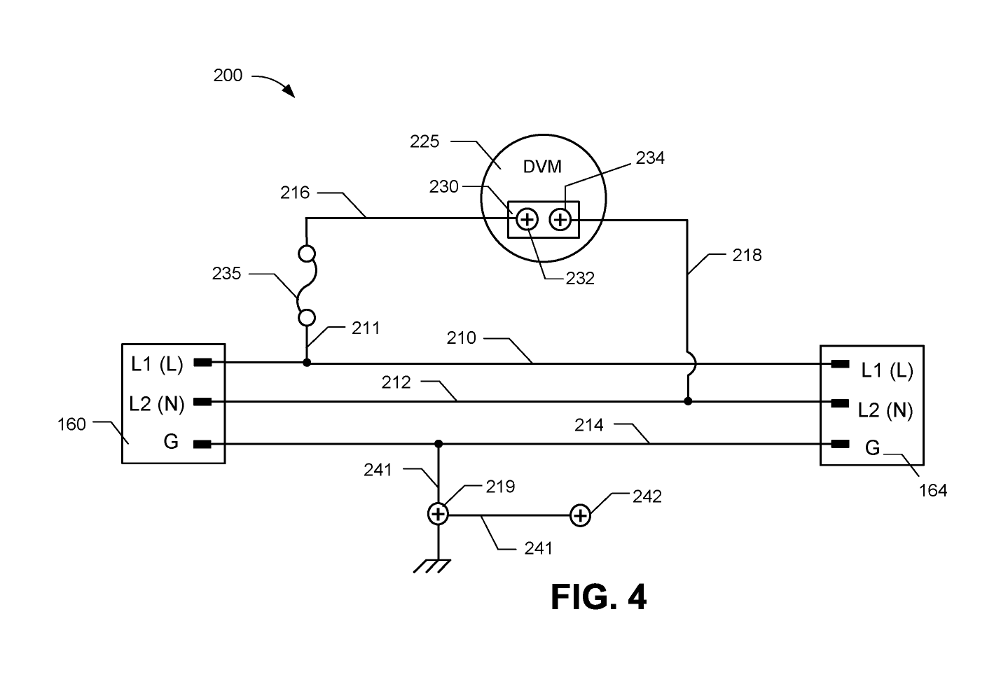

FIG. 4 is a diagram illustrating an embodiment of the portable electrical measurement assembly 100 of FIG. 2. Specifically, FIG. 4 shows the electrical measurement assembly 100 in an electrical circuit 200. While the electrical measurement assembly 100 includes cables or service cords and connectors 160, 164 that extend beyond or are entirely outside the housing 110 it should be understood that the connections or junctions illustrated schematically in FIG. 4 are preferably enabled within the housing 110.

As illustrated, the electric circuit 200 includes connectors 160, 164, a digital voltmeter 225 and a time-delay fuse 235. Respective male tabs and female sockets (not shown) provided with the connectors 160, 164 are electrically coupled in a one-to-one relationship via conductors 210, 212, 214. For simplicity of illustration each of the connector terminations are represented symbolically with a solid black rectangle.

In an example embodiment, connector 160 may be a male style or plug style connector that supports three electrically conductive tabs that extend from a face 161 (FIG. 2) of the connector 160. Connector 164 may be a female style connector arranged with three electrically conductive sockets within a housing of the connector 164. As indicated symbolically in the illustrated embodiment, the three tabs or blades of connector 160 provide separate electrically conductive connections to each of a line-in or “L1” node, a neutral (return) or “L2” node and a ground or “G” node. Those skilled in the art will recognize that alternate node labels “L” and “N” designate a 220 VAC circuit in Europe and “L1” and “L2” designate a 220 VAC circuit in the U.S. Similarly, the sockets within the connector 164 provide separate electrically conductive connections to the line-in, neutral and ground nodes. The three tabs or blades are arranged in registration with corresponding sockets arranged in a supply connector coupled to the line-in electrical supply 12 (both not shown) that can be attached to the connector 160. The three sockets in connector 164 are arranged in registration with corresponding tabs or blades arranged in a plug connector (not shown) that can be attached to the connector 164. Such a plug type connector may be provided on the distribution assembly 13 which may include a yoke to couple the line-in supply voltage to the hoist mechanisms 16, 18. Accordingly, as presented in FIG. 1, the electrical measurement assembly 100 can be inserted in-line between a building provided or other electrical source and one or more electrically powered motors or other equipment present on a work platform 10.

The connectors 160, 164 are arranged such that a respective termination at the end of the conductors 210, 212, 214 are separated from one another and protected from moisture and other contaminants. The connectors 160, 164 may be rated for safe operation when coupled to an electrical supply of up to 250 volts (VAC) and a load of up to 30 amperes (A). Example connectors are commercially available from Hubbell Incorporated through distributors in North America and Europe. The conductors 210, 212, 214 may be implemented with 10 American wire gauge (AWG) wire, which defines a desired diameter of a single solid round conductor of non-ferrous metal. Such a wire has a resistance of approximately 1 mOhm/ft. or 3.3 mOhm/m.

The conductors 210, 212, 214 may be arranged in a service cord or insulated cable 150 having a thermoset rubber jacket that surrounds respective oil-resistant and color-coded insulating sleeves. An internal oil-resistant insulating jacket may surround the conductors 210, 212, 214 within the rubber jacket. Such a service cord is commercially available and provides safe operation for operating voltages up to 600 V can be submerged and remains flexible when exposed to temperatures from −40° C. to 90° C. When color-coded, the conductor 210 will be in a white insulating sleeve, the conductor 212 will be in a black insulating sleeve and the conductor 214 will be in a green insulating sleeve. The conductors 210, 212, 214 may be formed with a first desired length of service cord or insulated cable 150 and a second desired length of service cord or insulated cable 152 that are coupled to each other within the housing 110.

As further illustrated in FIG. 4, the time-delay fuse 235 and the digital voltmeter 225 are coupled in series between the “L” node or conductor 210 and the “N” node or conductor 212. Conductors 211 and 216 are electrically coupled to opposite ends of the time-delay fuse 235. The conductor 211 is electrically coupled at a first end to the conductor 210 as represented schematically with the solid circle. This connection can be made via an appropriately sized splice connector commonly referred to as a wire-nut or the connection can be made at terminal in a block that is separated and/or electrically insulted from the remaining conductors in the housing 110. The conductor 211 is electrically coupled at the opposed or second end at a first connection on a cartridge-style fuse holder 130 (which electrically couples the time-delay fuse 235 when present therein) or a terminal in a block that is separated and/or electrically insulted from the remaining conductors in the housing that is coupled to the fuse holder 130. A first end of the conductor 216 is electrically coupled at an opposed end of the cartridge-style fuse holder 130 or a terminal in a block that is separated and/or electrically insulted from the remaining conductors in the housing 110 that is coupled to the opposed end of the fuse holder 130. A second end of the conductor 216 is coupled to the digital voltmeter 225 via a terminal 232 in the terminal block 230. A first end of the conductor 218 is coupled to the digital voltmeter 225 at terminal 234 in the terminal block 230. A second end of the conductor 218 is electrically coupled to the conductor 212 using an appropriately sized splice connector or a terminal in a terminal block that is separated and/or electrically insulated from the remaining conductors in the housing 110. The conductors 211, 216, 218 may be implemented with 16 AWG wire insulated in a sleeve with a color different from white, black or green.

As further shown in FIG. 4, when the housing 110 and the removable cover 140 are made from a conductive metal, the conductor 241 is electrically coupled at a first end to the conductor 214 as represented schematically with the solid circle. This connection can be made via an appropriately sized splice connector commonly referred to as a wire-nut or the connection can be made at a terminal in a block that is separated and/or electrically insulted from the remaining conductors in the housing 110. The conductor 241 is electrically coupled at a mid-point to the housing 110 via a ground tab and a fastener 219. In addition, the conductor 241 is electrically coupled to the housing cover 140 via a ground tab and a fastener 242. When terminals in terminal blocks and/or fasteners are used to couple exposed portions of conductors or wires in the housing 110, the respective wire ends may be soldered, bonded or crimped to a tab-style connector (not shown) to provide a physical and electrically conductive connection when such a connector is pressed between a base of a terminal or a portion of the housing and a head portion of a metal fastener. Alternatively, one or more electrical connections can be made by soldering wire ends to appropriate terminals and thereafter encapsulating or covering the conductors and terminals with an electrically insulating gel.

An example time-delay fuse 235 is safe for operating voltages up to 250 VAC and a meter load current of up to 0.25 A. Such a time-delay fuse 235 and a corresponding panel mounted fuse holder 130 are commercially available from Cooper Bussmann of St. Louis, Mo., U.S.A.

An example panel mounted digital voltmeter 225 is safe for in-line root means square (RMS) measurements of service voltages from about 85 to 264 VAC at frequencies between about 47 to 63 Hz. Such a digital voltmeter 225 is commercially available from Murata Power Solutions of Mansfield, Mass., U.S.A.

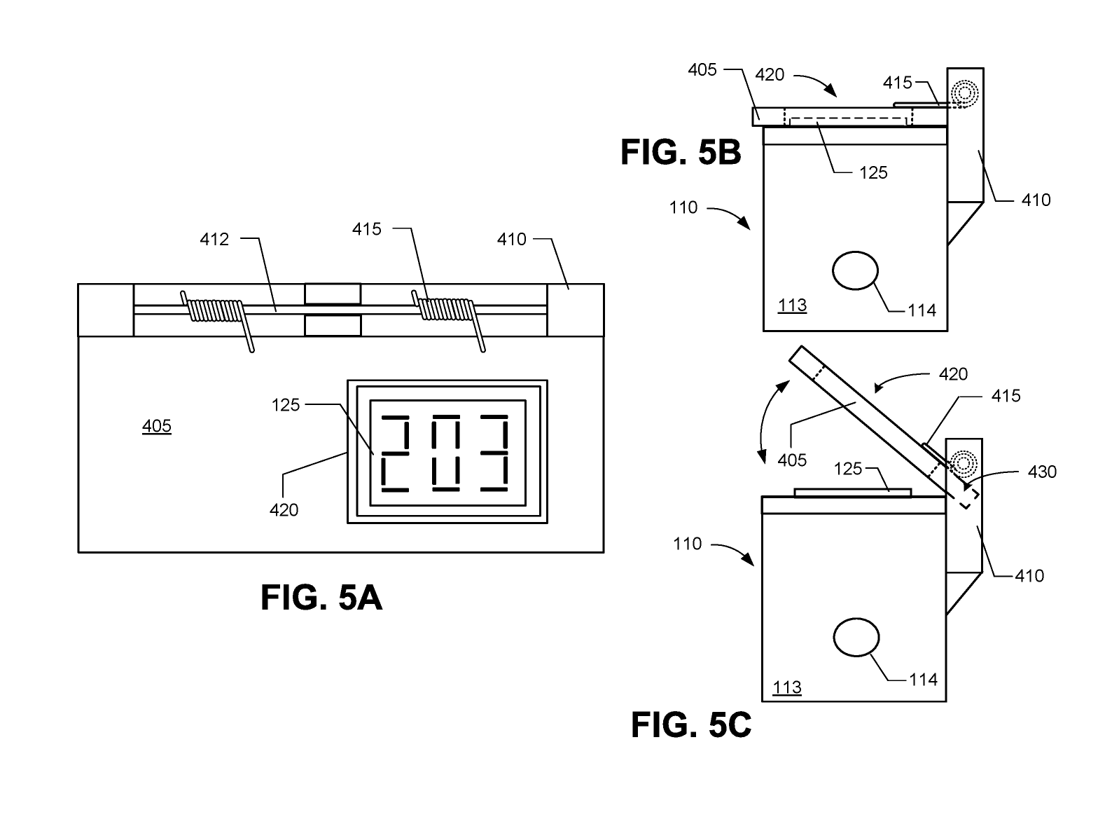

FIGS. 5A, 5B and 5C schematically illustrate an alternative embodiment of the portable electrical measurement assembly 100 of FIG. 2 arranged with a protective cover 405. For simplicity of illustration and description, the insulated cables, connectors and clamps that extend beyond the external surfaces of the housing 110 are omitted form the embodiment depicted in FIGS. 5A-5C.

As indicated in a top plan view in FIG. 5A, the protective cover 405 may form an opening 420 that is arranged in registration with the display 125 of the digital voltmeter 225 and a recess that accommodates the cap 131 to enable observation of the display 125 when the protective cover 405 is resting against the removable cover 140 of the housing 110. A translucent window or insert can be arranged in, above or below the opening 420 to further protect the display 125. Alternatively, a screen can be arranged in or over the opening 420 as may be desired.

As shown in side plan views in FIGS. 5B and 5C, in such an arrangement, the housing 110 may be modified with a structure 410 that provides a pivot point 430 about which the protective cover 405 can be rotated to expose the cap 131 to permit operator access to the time-delay fuse 235 in the cartridge-style fuse holder 130. An axle 412 is supported in the structure 410. One or more coil springs 415 arranged about the axle 412 provide a bias force to keep the protective cover 405 resting against removable cover 140. Alternatively, extension member(s) may be connected to the protective cover 405 which would permit the protective cover 405 to rotate about the axle 412.

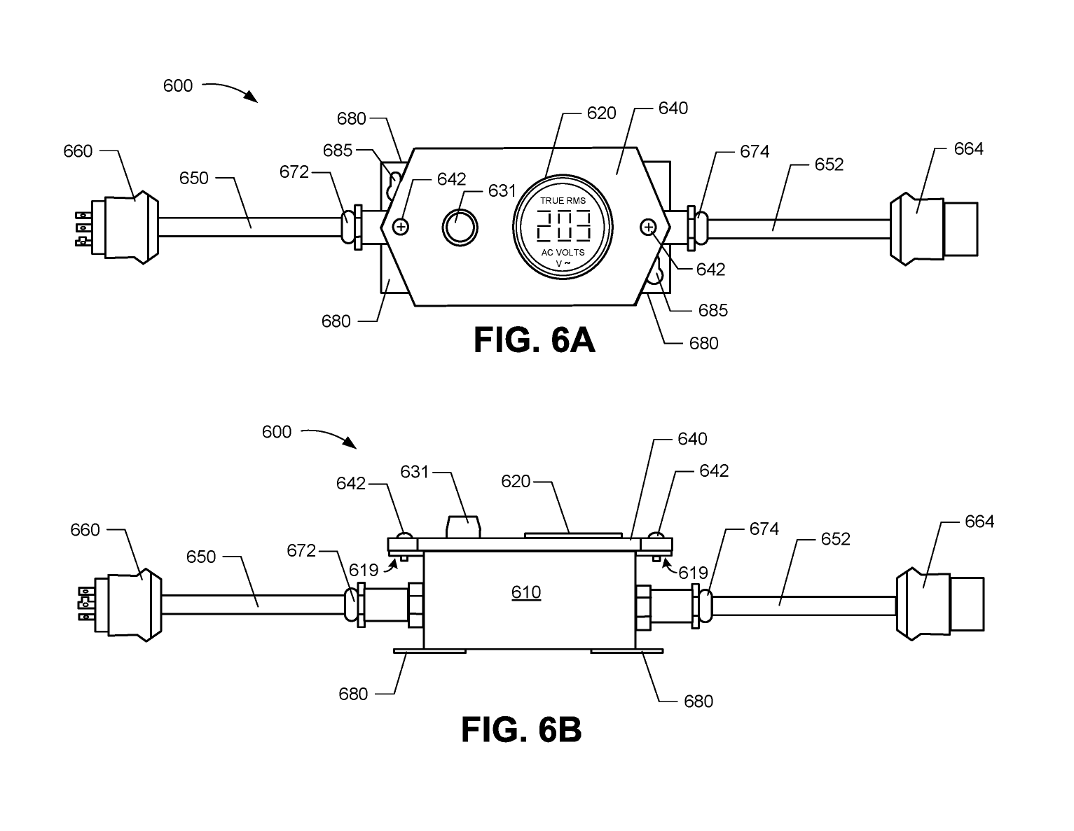

FIG. 6A and FIG. 6B include schematic illustrations of an alternative embodiment of the portable electrical measurement assembly 600 in a top plan view and a front plan view, respectively. In this arrangement, the housing 610 includes left-side and right-side mounting tabs 619 that extend beyond the right-side and left-side walls of the housing 610. This arrangement maximizes access to the cavity formed by the housing 610. The tabs 619 include respective threaded openings to receive corresponding threaded fasteners 642, which hold the cover 640 to the housing 610. When the fasteners 642 are placed in the respective openings in the cover 640 and tightened a gasket seals the underside surface of the cover 640 against the upward facing surfaces of the walls of the housing 610 to protect the various electrical connections within the cavity of the housing 610.

In addition, mounting tabs 680 extend from the lowermost surface of the housing 610. Each of the tabs 680 forms at least one slotted opening 685 for receiving the head of a mounting fastener which may be provided along one of the various structures of a portable work platform (not shown). When the mounting tabs 680 are engaged with corresponding mounting fasteners, the housing 610 is supported by the work platform.

Plug-style connector assembly 660 is electrically coupled at a distal end of the electrical conductors of insulated cable 650 which extends through cable clamp 672 and a left-side wall into the cavity of the housing 610. The cable clamp 672 provides stress relief for the insulated cable 650 by annularly compressing the external insulator of the insulated cable 650. In this way, the cable clamp 672 provides a first seal that prevents the passage of moisture and other contaminants from entering the cavity of the housing 610. The cable clamp 672 is further arranged with an external threaded nut and an internal threaded nut (not shown) that when tightened fixes the cable clamp 672 against the opposed surfaces of the left-side wall of the housing 610. In this way, the cable clamp 672 provides additional stress relief for the insulated cable 650 and provides a second seal that prevents the passage of moisture and other contaminants from entering the cavity of the housing.

Female-style connector assembly 664 is electrically coupled at a distal end of the electrical conductors of insulated cable 652 which extends through cable clamp 674 and a right-side wall into the cavity of the housing 610. When the corresponding internal and external threaded nuts are tightened, the cable clamp 674 provides stress relief for the insulated cable 652 and fixes the cable and connector at the right-side wall of the housing 610 in the same manner as cable clamp 672. In addition, the cable clamp 674 provides corresponding seals at the right-side wall of the housing 610 and with the outer surface of the insulated cable 652. Both seals prevent the passage of moisture and other contaminants from entering the cavity of the housing 610.

As introduced and described, the portable electrical measurement assembly provides a safe, compact, current limited, circuit that provides an inline measure of the electrical load present on a deployed work platform 10. When the portable electrical measurement assembly is coupled between the building supply and the work platform 10 the voltage under load is measured and presented.

The described portable electrical measurement assembly (with two connectors) can be readily modified to be installed permanently on a work platform 10 by coupling the conductors in the insulated cable 152 to a hoist supply circuit on the work platform. The capability to observe the AC voltage reaching the hoist before and during use can now be made permanent with this use of the assembly.

Other contemplated modifications include forming the first and second openings along adjacent walls of the housing or even the same wall as may be desired. Such alternatives may be accompanied by a corresponding change in the length of one or both of the insulated cables as may be required for one or more specific work platforms. In addition, one or both of the openings for a fuse holder and the measurement device may be formed in one or more of the walls of the housing rather than in the removable cover. For example, it might be desirable to mount the fuse holder in one of the side walls where it might be somewhat obscured and protected by the removable cover and a mounting tab or tabs. While the illustrated embodiments show the mounting tabs extending from or connected to a surface of the housing opposed from display portion of the measurement device, the portable measurement assembly is not so limited. For example, it may be desirable to mount the display portion of the measurement device along an adjacent surface from a surface supporting the mounting tabs when a work platform has mounting appendages that would support the measurement assembly at or near a level where it the display is observable to workers on the platform.

One or more illustrative or exemplary embodiments of the electrical measurement assembly have been described above. However, it is to be understood that the assembly is defined by the appended claims and is not limited to the specific embodiments described.

Reference Numbers Introduced in the Illustrated Embodiments

| | |
|---|---|
| 10 | work platform |
| 11 | frame |
| 12 | line-in electrical supply |
| 13 | distribution assy. |
| 14 | line-out (to load) |
| 15 | suspension cable |
| 16 | hoist mechanism |
| 17 | suspension cable |
| 18 | hoist mechanism |
| 100 | portable measurement assy. |
| 110 | housing |
| 111 | surface |
| 112 | passage |
| 113 | surface |
| 114 | passage |
| 115 | base |
| 116 | passage |
| 117 | surface |
| 118 | passage |
| 120 | measurement device |
| 125 | display |
| 130 | fuse holder |
| 131 | cap |
| 140 | removable cover |
| 142 | fastener |
| 145 | gasket |
| 150 | insulated cable |
| 152 | insulated cable |
| 160 | connector assy. |
| 161 | face |
| 162 | tab(s) |
| 164 | connector |
| 165 | face |
| 166 | opening(s) |
| 167 | socket(s) |
| 171 | threaded nut |
| 172 | threaded cable clamp |
| 174 | threaded cable clamp |
| 175 | threaded nut |
| 180 | tab(s) |
| 185 | opening(s) |
| 200 | circuit |
| 210 | conductor |
| 211 | conductor |
| 212 | conductor |
| 214 | conductor |
| 216 | conductor |
| 218 | conductor |
| 219 | bonding element (housing) |
| 225 | digital voltmeter |
| 230 | terminal block |
| 232 | fastener |
| 234 | fastener |
| 235 | time-delay fuse |
| 241 | conductor |
| 242 | bonding element (cover) |
| 405 | protective cover |
| 410 | structure |
| 412 | axle |
| 415 | coil spring |
| 420 | opening |
| 430 | pivot axis |
| 610 | housing |
| 619 | flange |
| 620 | measurement device |
| 631 | fuse holder |
| 640 | cover |
| 642 | fastener |
| 650 | insulated cable |
| 652 | insulated cable |
| 660 | connector assy. |
| 664 | connector assy. |
| 672 | cable clamp |
| 674 | cable clamp |
| 680 | tab(s) |
| 685 | opening(s) |

I claim:

1. A portable measurement assembly suitable for a work platform, comprising:
a housing arranged with:
a first passage arranged to receive a line-in electrical supply,
a second passage arranged to provide a line-out to a load, and
a measurement device electrically coupled to the line-in electrical supply.

2. The assembly of claim 1, wherein the measurement device electrically coupled to the line-in electrical supply is responsive to an electrical potential under a load.

3. The assembly of claim 2, wherein the measurement device electrically coupled to the line-in electrical supply provides an observable display representing AC voltage introduced by the line-in electrical supply.

4. The assembly of claim 1, wherein the first passage is arranged in a first surface of the housing, the second passage is arranged in a second surface of the housing, the second surface opposed to the first surface.

5. The assembly of claim 1, further comprising:
a current limiting device coupled in series with the measurement device.

6. The assembly of claim 5, further comprising:
a removable cover that provides a third passage arranged to provide access to a cavity formed by the housing for electrical conductors coupled to the measurement device and a fourth passage arranged to provide access to the cavity for a current limiting device coupled in series with the measurement device.

7. The assembly of claim 5, wherein the current limiting device is a fuse.

8. The assembly of claim 5, wherein the current limiting device and the measurement device are coupled between a line-in conductor and a return conductor in a cavity of the housing.

9. The assembly of claim 1, further comprising:
a first three-conductor insulated cable extending beyond the housing from the first passage.

10. The assembly of claim 9, wherein the first three-conductor insulated cable is terminated in a first electrically insulated and weather proof connector.

11. The assembly of claim 10, wherein the first electrically insulated and weather proof connector includes three electrically conductive tabs extending from a face of the first electrically insulated and weather proof connector.

12. The assembly of claim 9, wherein the first three-conductor insulated cable is secured by an annular clamp at the first passage.

13. The assembly of claim 9, further comprising:
a second three-conductor insulated cable extending beyond the housing from the second passage.

14. The assembly of claim 13, wherein the second three-conductor insulated cable is secured by an annular clamp at the second passage.

15. The assembly of claim 13, wherein the second three-conductor insulated cable is terminated in a second electrically insulated and weather proof connector.

16. The assembly of claim 15, wherein the second electrically insulated and weather proof connector includes three electrically conductive sockets that are exposed via openings at a face of the second electrically insulated and weather proof connector.

17. The assembly of claim 1, wherein the line-in electrical supply is provided via a cable coupled to a building, the measurement device provides an indicator of an appropriate portable transformer that can convert the under load line-in electrical supply to a desired electrical potential on the work platform.

18. The assembly of claim 1, wherein the housing is arranged with a protective cover that surrounds at least a portion of the measurement device.

19. The assembly of claim 18, wherein the protective cover further surrounds an access port to a current limiting device.

20. The assembly of claim 1, wherein the housing is arranged with at least one mounting tab extending therefrom, the at least one mounting tab forming an opening for receiving an appendage of the work platform.
